(19) United States
(12) Patent Application Publication
(10) Pub. No.: US 2022/0209308 A1
(43) Pub. Date: Jun. 30, 2022

(54) MODULE BATTERY SYSTEM

(71) Applicant: SJ Tech Co., Ltd., Hoengseong-gun, Gangwon-do (KR)

(72) Inventors: Sang Oog JEON, Goyang-si, Gyeonggi-do (KR); Seung Hyeon LEE, Wonju-si, Gangwon-do (KR); Soon Kwang KWON, Wonju-si, Gangwon-do (KR); Deuk Hyoun KOO, Wonju-si, Gangwon-do (KR)

(21) Appl. No.: 17/609,891

(22) PCT Filed: Sep. 10, 2020
(86) PCT No.: PCT/KR2020/012213

§ 371 Date: Nov. 9, 2021

(30) Foreign Application Priority Data
Nov. 11, 2019 (KR) 10-2019-0143507

(51) Int. Cl. H01M 10/42; H02J 7/00; H01M 50/269; H01M 10/48; G01R 31/36; G01R 31/3835; G01R 31/374

(52) U.S. Cl. CPC H01M 10/425; H02J 7/0031; H02J 7/0024; H01M 50/269; H01M 10/482; H01M 2010/4278; H01M 10/486; G01R 31/3646; G01R 31/3835; G01R 31/374; H01M 2010/4271; H01M 10/488

(57) ABSTRACT

A module battery system is disclosed and, more specifically, a module battery system which can select and output a desired capacity through a combination of a plurality of battery modules and notify the outside of an abnormal situation through a self-diagnosis and performs a self-protection operation as necessary at the same time.

### TECHNICAL FIELD

The present invention relates to a module battery system, and more specifically, to a module battery system which may select and output a desired capacity through a combination of a plurality of battery modules and notify the outside of an abnormal situation through a self-diagnosis and performs a self-protection operation as necessary at the same time.

### BACKGROUND ART

Recently, with an increase in interest about new renewable energy and smart grids, studies on an energy storage system (ESS) are being actively conducted as related technology.

An ESS relates to a system capable of improving energy efficiency by storing generated electricity in grid energy storages and supplying the electricity when the electricity is most needed so that the electricity is used and serves to stably supply power while a power supplier and a consumer exchange information in real time.

The ESS generally includes a battery, a battery management system (BMS), a power conversion system (PCS), and an energy management system (EMS). First, the battery is a medium which serves to store energy and discharge the electricity as necessary, and the BMS serves to manage the battery by measuring a voltage, a current, a temperature, and the like of the battery in real time to protect the battery from overcharge, discharge, and the like.

In addition, the PCS serves to convert direct current (DC) power stored in the battery to alternating current (AC) power and supply the AC power to the grid energy storage or serves to convert AC power supplied from the grid energy storage to DC power and store the DC power in the battery, and the EMS serves to efficiently manage power by monitoring and controlling a state of the battery and a state of the PCS.

Among them, a secondary battery capable of being repeatedly charged and discharged is used as the battery of the ESS, and since a demand for the ESS increases, and a required electric capacity increases gradually, the secondary battery is used as a battery pack type capable of storing and supplying high capacity power.

The battery pack is formed such that several battery cells or a plurality of battery modules are bound by being connected in series or in parallel in a pack form, a plurality of secondary batteries are accommodated in one module case to constitute one battery module, and the plurality of battery modules are accommodated in one pack case to constitute one battery pack.

Recently, the ESS is used for not only portable electronic devices but also medium-to-large apparatuses, such as electric vehicles, or power supplied to home, and there are a required voltage and a required capacity of the battery for each system.

Due to the required voltage and capacity used in each system, since the number of kinds of batteries increases and the conventional systems are configured to use dedicated batteries, there is a problem in that the use of the battery is limited.

In order to solve such a problem, a technology which allows a user to directly adjust a voltage and a capacity required by the user by combining battery modules constituting a battery pack is developed, and as one example, in Korean Patent Publication No. 10-1602877, an energy storage apparatus configured to supply power from an individual battery module to a controller is disclosed.

That is, in the conventional technology, the ESS includes a battery part in which a plurality of battery modules are stacked, a module selection switch part connected to each of the battery modules in the battery part, a charging module part for charging the battery module, a voltage control part for controlling a voltage of power output from the battery part, an output port for transmitting the power from the voltage control part to an external device, and a controller connected to the battery module to control the voltage output from the battery pack. However, in the conventional technology, since the plurality of battery modules are used sequentially one by one so that one battery module thereof is used, it is difficult to use in a system which requires large capacity power, and there is a disadvantage in that a usable voltage and a usable capacity are limited.

In addition, the conventional energy storage apparatus or battery according to the conventional technology does not have a self-diagnosis function or has an insufficient self-diagnosis function, and there is a problem in that, when it is recognized through the self-diagnosis that an abnormal situation occurs, the abnormal situation should be solved by only an external system.

### Technical Problem

The present invention is directed to providing a module battery system in which a plurality of battery modules are selectively connected in series or in parallel to allow a user to select and use a voltage and a capacity required by the user and which notifies the outside of an abnormal situation through a self-diagnosis and performs a self-protection operation as necessary at the same time.

### Technical Solution

One aspect of the present invention provides a module battery system including a plurality of battery modules, a voltage converter installed to be connected to an output terminal of the battery module, and a battery management system (BMS) module which is installed between and connected to the battery module and the voltage converter, controls the battery module, and checks whether an abnormality occurs in the battery module.

The BMS module may include a communication module which allows wireless communication between the battery modules and allows communication with an external device, a battery combination module which selectively connects the battery modules in series or in parallel, a self-diagnosis module which determines whether an abnormality occurs in the battery module through a self-diagnosis, and an alarm generation module which generates an alarm when the self-diagnosis module detects the abnormality occurring in the battery module.

The BMS module may include a problem solving module which solves a problem when the self-diagnosis module detects the abnormality occurring in the battery module.

The problem solving module may include a first problem solving module, a second problem solving module, a third problem solving module, and a fourth problem solving module which are configured to solve a cell voltage problem, a pack voltage problem, a temperature problem, and a current problem of the battery module.

When a voltage of a specific cell of the battery module is not checked, the first problem solving module may be configured to block an output to the outside, measure a voltage of all cells excluding the cell in which an abnormality occurs and a pack voltage, and infer a value, which is calculated by subtracting the measured voltage of the all cells from the measured pack voltage, as the voltage of the cell.

When a pack voltage of the battery module is not checked, the second problem solving module may be configured to block an output to the outside, measure a voltage of all cells and a pack voltage, and to recognize the measured voltage of the all cells as the pack voltage when it is determined that there is a pack voltage sensing abnormality.

When a temperature of the battery module is not measured, the third problem solving module may be configured to block an output to the outside, continuously measure a temperature, determine a case in which a value of the measured temperature expresses a high temperature or low temperature, which is different from a value of the measured nearby temperature, as a sensing error, and check a temperature which is performed by temperature sensing excluding temperature sensing in which abnormality occurs.

The self-diagnosis module may perform the self-diagnosis of the battery module through an abnormal state check operation of checking whether the abnormality occurs in each of the battery modules, an alarm generation operation of outputting and notifying the outside of content of an abnormal state when the abnormality occurs in the battery module, a stand-by operation of waiting for a predetermined time after generating an alarm, and an output block operation of blocking an output to the outside when the abnormal state is not solved for the stand-by operation.

In the abnormal state check operation, it may be checked whether a cell voltage abnormality, a pack voltage abnormality, a temperature abnormality, or a current abnormality occurs in each of the battery modules.

When an abnormality occurs in a specific battery module among the plurality of battery modules and the specific battery module is replaced with a new battery module, the self-diagnosis module may control the battery modules to operate normally by measuring differences in voltage and capacity between the battery modules and controlling an output for each battery module even when the battery module is replaced.

The module battery system may further include an external server which is connected to the BMS module through wired or wireless communication to control the BMS module and inputs a command to operate the battery modules.

The external server may include a database which stores information needed to control the BMS module and pieces of information about states of the battery modules.

### Advantageous Effects

According to the present invention, a module battery system has a great effect in that a self-diagnosis of the system including a plurality of battery modules can be performed and a self-protection operation can be performed according to content detected through the self-diagnosis at the same time so that stability and reliability of the entire system can be improved.

In addition, according to the present invention, the module battery system has an additional effect of operating in conjunction with an external apparatus and being applied to various fields to be used by selectively connecting the battery modules in series or in parallel through a relatively simple structure and allowing a user to select and use a voltage and a capacity required by the user.

### DESCRIPTION OF DRAWINGS

FIG. 1 is a schematic view illustrating a configuration of a module battery system according to the present invention.

FIG. 2 is a conceptual view illustrating a detailed configuration of a battery management system (BMS) module of the present invention illustrated in FIG. 1.

FIG. 3 is a flowchart illustrating a process of performing a self-diagnosis of a battery module by a self-diagnosis module of the present invention illustrated in FIG. 2.

### MODES OF THE INVENTION

Hereinafter, exemplary embodiments of a module battery system according to the present invention will be described in detail with reference to the accompanying drawings.

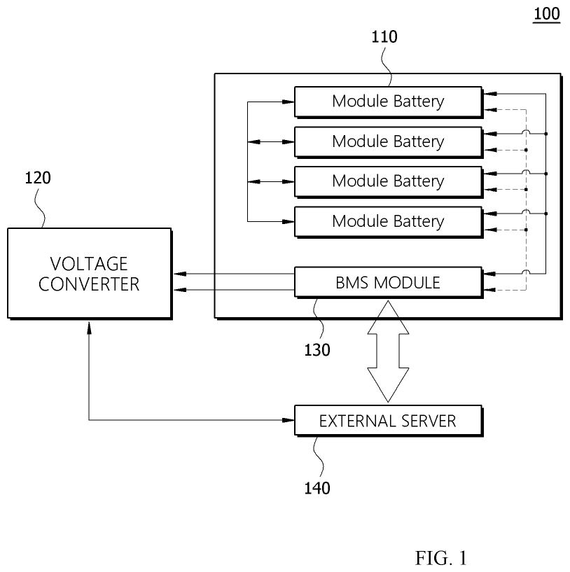

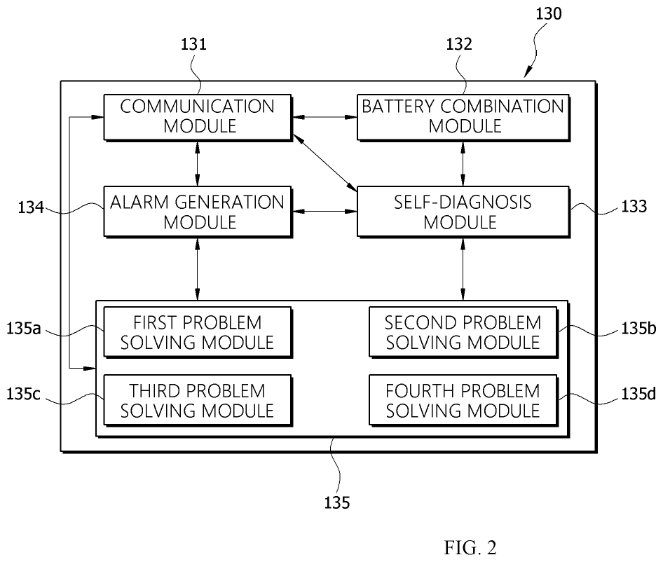

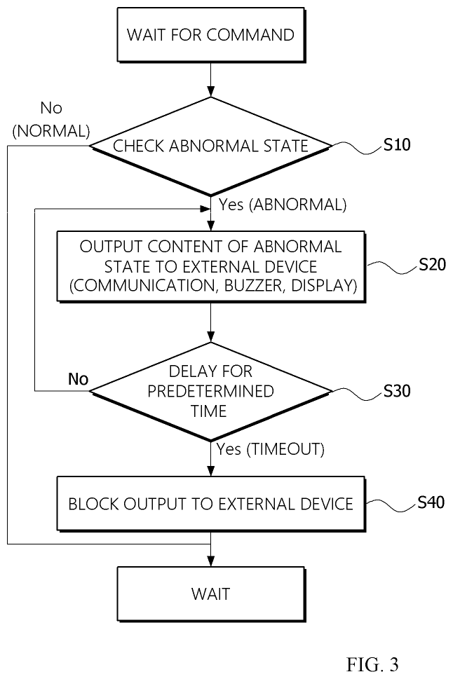

FIG. 1 is a schematic view illustrating a configuration of a module battery system according to the present invention, FIG. 2 is a conceptual view illustrating a detailed configuration of a battery management system (BMS) module of the present invention illustrated in FIG. 1, and FIG. 3 is a flowchart illustrating a process of performing a self-diagnosis of a battery module by a self-diagnosis module of the present invention illustrated in FIG. 2.

The present invention relates to a module battery system 100 in which a plurality of battery modules are combined and which allows a desired capacity to be selected and output, notifies the outside of an abnormal situation through a self-diagnosis, and performs a self-protection operation as necessary at the same time. As illustrated in FIG. 1, the module battery system 100 mainly includes battery modules 110, a voltage converter 120, a BMS module 130, and an external server 140.

More specifically, first, secondary batteries capable of being repeatedly charged and discharged are accommodated in a module case to constitute the battery module 110, and the plurality of battery modules 110 may be installed to be connected in series or in parallel by an external command from the external server 140, which will be described below, or by a battery combination module 132 of the BMS module 130, which will be described below, so that a user may directly adjust a voltage and a capacity by combining the battery modules 110.

In this case, a BMS device (not shown) is provided in each of the battery modules 110 so that interiors of the battery modules 110 may be diagnosed and checked, and the BMS module 130, which will be described below, may be configured to integrally manage and control the BMS devices provided in the battery modules 100.

Next, the voltage converter 120 is installed to be connected to an output terminal of the battery module 110 and serves to convert a voltage output from the battery module 110 so that the module battery system 100 according to the present invention may be used in various fields due to the voltage converter 120.

That is, since a voltage provided from the battery module 110 may be converted to 5 V, 12 V, 24 V, 48 V, 110 V, or 220 V by the voltage converter 120, the module battery system 100 according to the present invention is used for leisure such as camping and fishing or is used by applying to an electric scooter or electric bicycle. When other types of outside work are performed, the module battery system 100 is configured to be used by connecting a work light or power tool and the voltage converter 120 so that the module battery system 100 can be applied to an energy storage system (ESS) industry.

In this case, a power conversion system (PCS) may also be used as the voltage converter 120.

Next, the BMS module 130, which is disposed between and connected to the plurality of battery modules 110 and the voltage converter 120, serves to control the battery modules 110 and check whether an abnormality occurs in the battery module 110 or the like, and the BMS module 130 measures a current, a voltage, and a temperature of a charger during charging like a conventional BMS device, notifies the user of a remaining capacity and a lifetime of a battery, and serves to detect a risk of a fire or explosion due to overcharge, overdischarge, overcurrent, or the like to maintain safety and the like.

Meanwhile, the BMS module 130 used in the present invention includes a communication module 131, the battery combination module 132, a self-diagnosis module 133, and an alarm generation module 134. First, the communication module 131 serves to allow wireless communication between the battery modules 110 and allow communication to the external device.

That is, the battery modules 110 used in the present invention are operated by commands, and the commands may be externally input from the external server 140, which will be described below, or may be internally input through communication between the battery modules 110.

Accordingly, the communication module serves to allow the commands related to operations of the battery modules 110 to be accurately transmitted to the battery modules 110 and is configured to transmit the commands from the external server 140 to the battery modules 110 or to allow wireless communication between the battery modules 110 so that reliability of the module battery system 100 according to the present invention can be improved.

Next, the battery combination module 132 serves to allow a method of connecting the battery modules 110, that is, connection in series or in parallel, to be selected, and the battery combination module 132 is configured to select the method of connecting the battery modules 110 so as to connect the battery modules 110 when a command is input from the external server 140 which will be described below.

In this case, the battery combination module 132 may also be configured to connect some battery modules 110 in series or in parallel when a problem occurs such that abnormalities occur in some battery modules 110 or the like or as necessary.

Next, the self-diagnosis module 133 serves to check whether an abnormality occurs in each of the battery modules 110 in real time through a self-diagnosis and is configured to notify the external server 140 of an abnormality occurrence situation through the communication module 131 when an abnormality is detected and to generate an alarm through an alarm generation module 134 which will be described below.

In this case, abnormal states, which may be detected by the self-diagnosis module 133, may include a cell voltage abnormal state, a pack voltage abnormal state, a temperature abnormal state, a current abnormal state, and the like of each of the battery modules 110, and the self-diagnosis module 133 is configured to detect overcharge, overdischarge, and sensing errors of a cell voltage and a pack voltage, a high temperature, a low temperature, and a temperature sensing error, a overcharge current, and an overdischarge current.

In addition, when an abnormality occurs in a specific battery module 110 among the plurality of battery modules 110, a case in which the battery module 110 needs to be replaced with a new battery module 110 may occur. In this case, the self-diagnosis module 133 also serves to allow the module battery system 100 according to the present invention to operate normally by measuring differences in voltage and capacity between the battery modules 110 and controlling outputs of the battery modules 110 even after the battery module 110 is replaced.

Next, the alarm generation module 134 serves to generate an alarm and notify the user or the external server 140 of an abnormality when the abnormality occurs in the battery module 110. The alarm generation module 134 is configured to generate an alarm sound and notify the user of the abnormality and notify a manager of the occurrence of the abnormality in the battery module 110 to at the same time by transmitting an abnormality occurrence situation to the external server 140 through the communication module 131 when the self-diagnosis module 133 detects the abnormality in the battery module 110.

In addition, when a display (not shown) for checking the battery modules 110 is provided, the alarm generation module 134 may also be configured to display an abnormal state on the display to notify the user of the abnormal state.

Meanwhile, as shown in FIG. 3, a process of detecting an abnormal situation using the self-diagnosis module 133 includes an abnormal state check operation S10, an alarm generation operation S20, a stand-by operation S30, and an output block operation S40. First, the abnormal state check operation S10, which is an operation of checking whether an abnormality occurs in each of the battery modules 110, determines whether the abnormality occurs in each of the battery modules 110 by checking a cell voltage, a pack voltage, a temperature, and a current described above through sensing information about the battery modules 110 received through the communication module 131.

Next, the alarm generation operation S20 is a process of allowing the alarm generation module 134 to generate an alarm and to transmit and output content of an abnormal state to the external server 140 or the display through the communication module 131 when the abnormality in the battery module 110 is detected by the self-diagnosis module 133 in the abnormal state check operation S10.

Next, the stand-by operation S30 relates to an operation of standing by for a predetermined time after the alarm is generated in the alarm generation operation S20 and the content of the abnormal state is transmitted. In this case, the predetermined time is a time required for the user or manager to take an action to solve the abnormal state after the content of the abnormal state is transmitted to the external server 140 or display. Since the time required for solving may be changed according to the content of the abnormal state, a stand-by time for each abnormal state may be preset and stored in the self-diagnosis module 133 or a database of the external server 140 which will be described below.

In this case, when a problem related the abnormal state is not solved for the stand-by operation S30, the alarm generation module 134 continuously generates the alarm until the stand-by operation S30 is finished, and when the problem is solved for the stand-by operation S30, the alarm generation module 134 stops the alarm generation according to a command from the external server 140, and the self-diagnosis module 133 continuously checks whether an abnormality occurs in the battery module 110.

Next, the output block operation S40 relates to an operation of blocking an output to the external device from the battery module 110. The self-diagnosis module 133 or a problem solving module 135, which will be described below, is configured to stop a use of the module battery system 100 by blocking the output of the battery module 110 when the problem related to the abnormal state is not solved in the stand-by operation S30.

Meanwhile, as shown in FIG. 2, the BMS module 130 of the module battery system 100 according to the present invention may further include the problem solving module 135. The problem solving module 135 serves to allow the module battery system 100 to solve a problem without external help when the self-diagnosis module 133 detects an abnormality in the battery module 110.

More specifically, when the abnormality in the battery module 110 is detected by the self-diagnosis module 133, the problem solving module 135 determines whether the problem may be solved by itself. When it is determined that the problem may not be solved, the problem solving module 135 waits in the stand-by operation S30 as described above so that the self-diagnosis module 133 blocks an output to the external device. When it is determined that the problem may be solved by itself, the problem is solved by the problem solving module 135. To this end, the problem solving module 135 includes first to fourth problem solving modules 135a, 135b, 135c, and 135d.

First, the first problem solving module 135a is used when a cell voltage abnormality occurs. When a cell voltage sensing error occurs, the first problem solving module 135a allows the module battery system 100 to be used temporarily by solving the error.

That is, when a cell voltage sensing problem occurs, cell overcharge or cell overdischarge may occur due to a cell which is not sensed. Accordingly, since a problem may occur in the module battery system 100, when it is detected that a specific cell voltage is not checked by the self-diagnosis module 133, the first problem solving module 135a blocks an output to the outside of the battery modules 110.

Then, in a state in which the output is blocked, the first problem solving module 135a measures a cell voltage of all cells excluding a cell in which an abnormality occurs and a pack voltage and calculates a difference between the measured pack voltage and the cell voltage of the all cells excluding the cell in which the abnormality occurs.

That is, since a cell voltage of the cell, in which the abnormality occurs, is calculated by subtracting the cell voltage of the all cells excluding the cell in which the abnormality occurs from the measured pack voltage, the first problem solving module 135a infers the cell voltage of the cell in which the abnormality occurs in this manner and allows the module battery system 100 to be used temporarily.

Next, the second problem solving module 135b is used when a pack voltage abnormality occurs, and when a pack voltage sensing error occurs, the second problem solving module 135b solves the error to allow the module battery system 100 to be used temporarily.

That is, when a pack voltage sensing problem occurs, a problem may be generated in the module battery system 100 due to overcharge or overdischarge of the battery module 110. When it is detected that a pack voltage is not checked by the self-diagnosis module 133, the second problem solving module 135b blocks an output to the outside of the battery modules 110.

Then, in a state in which the output is blocked, the second problem solving module 135b measures cell voltages of the all cells and a pack voltage. When a difference between the cell voltages and the pack voltage is greater than or equal to a preset error, the second problem solving module 135b determines that a pack voltage sensing abnormality occurs and recognizes the sum of the measured cell voltages as a pack voltage to allow the module battery system 100 to be used temporarily.

Next, the third problem solving module 135c is used when a temperature abnormality of the battery module 110 occurs and is mainly used when it is confirmed that a high temperature of the cell is checked by the self-diagnosis module 133 or when a temperature sensing problem occurs.

That is, when the high temperature of the cell is checked, or when the temperature sensing problem occurs, since a problem may occur in the entire module battery system 100, the third problem solving module 135c blocks an output to the outside from the battery module 110 when the high temperature is checked in the cell. In a state in which the output is blocked, the third problem solving module 135c continuously measures a temperature of the battery module 110. When it is measured that the temperature is within a tolerance, the third problem solving module 135c allows the module battery system 100 to be used again.

In addition, when sensing is not performed by a specific temperature sensor, similarly, the third problem solving module 135c blocks an output to the outside from the battery module 110. In a state in which the output is blocked, the third problem solving module 135c continuously measures a temperature of the battery module 110, determines a sensing error when a temperature sensor shows a high temperature value or low temperature value which is different from a nearby temperature value, checks a temperature using only remaining temperature sensors, and allows the module battery system 100 to be used temporarily.

That is, the plurality of temperature sensors are installed in the battery module 110, and when the temperature in the battery module 110 is increased, since the surrounding temperature sensors are influenced thereby, a measured temperature is normally increased. Accordingly, when a temperature is measured in reverse or a large error occurs, it may be determined as a sensing error.

Next, the fourth problem solving module 135d is used when a current abnormality occurs in the battery module 110. When a current charged to or discharged from a specific battery module 110 is higher than a preset tolerance, the fourth problem solving module 135d blocks an output to the outside from the battery module 110. In a state in which the output is blocked, the fourth problem solving module 135d continuously measures a current of the battery module battery, and when it is measured that the current is within the tolerance, the fourth problem solving module 135d allows the module battery system 100 to be used again.

Meanwhile, the module battery system 100 according to the present invention may further include the external server 140, and the external server 140 is connected to the BMS module 130 through wired or wireless communication and serves to control the BMS module 130 and to input commands to operate the battery modules 110 at the same time.

That is, the external server 140 is used to manage the module battery system 100 according to the present invention, and a plurality of module battery systems 100 are installed to be connected to one external server 140.

In this case, the external server 140 includes the database (not shown) to manage the module battery systems 100, and information about the BMS module 130 and the battery modules 110 constituting the module battery system 100 is stored in the database for each module battery system 100.

More specifically, the database of the external server 140 is configured to store information about states of the battery modules 110 constituting the module battery system 100, reference data for determining whether an abnormality occurs, information about a reference time for solving a problem according to an abnormality occurrence situation, information about a method for solving the abnormality occurrence situation, and the like so that the manager may manage the module battery system 100 and the BMS module 130 and the battery modules 110 which are included therein.

In addition, the pieces of the information stored in the database are configured to be updated periodically or as necessary so that the module battery system 100 according to the present invention can always be managed in an optimum state.

Therefore, according to the module battery system 100 according to the present invention, there are various advantages in that stability and reliability of the entire system can be improved because the self-diagnosis of the system including the plurality of battery modules 110 can be performed and the self-protection operation can be performed according to self-diagnosed content at the same time, and the module battery system 100 can be operated in conjunction with the external device and be applied to various fields for being used because the battery modules 110 can be selectively connected in series or in parallel, and a voltage and a capacity needed by the user can be selectively used.

Although the most exemplary embodiments have been described as described above, the present invention is not limited to the embodiments and is clear to those skilled in the art that the present invention may be variously modified without departing from the technical spirit of the present invention, such as utilizing a cloud service in consideration of a continuous increase in the number of the pieces of data stored in the database of the external server 140.

1. A module battery system comprising:
a plurality of battery modules;
a voltage converter installed to be connected to an output terminal of the battery module; and
a battery management system (BMS) module which is installed between and connected to the battery module and the voltage converter, controls the battery module, and checks whether an abnormality occurs in the battery module.

2. The module battery system of claim 1, wherein the BMS module includes:
a communication module which allows wireless communication between the battery modules and allows communication with an external device;
a battery combination module which selectively connects the battery modules in series or in parallel;
a self-diagnosis module which determines whether an abnormality occurs in the battery module through a self-diagnosis; and
an alarm generation module which generates an alarm when the self-diagnosis module detects the abnormality occurring in the battery module.

3. The module battery system of claim 2, wherein the BMS module includes a problem solving module which solves a problem when the self-diagnosis module detects the abnormality occurring in the battery module.

4. The module battery system of claim 3, wherein the problem solving module includes a first problem solving module, a second problem solving module, a third problem solving module, and a fourth problem solving module which are configured to solve a cell voltage problem, a pack voltage problem, a temperature problem, and a current problem of the battery module.

5. The module battery system of claim 4, wherein, when a voltage of a specific cell of the battery module is not checked, the first problem solving module is configured to block an output to an outside, measure a voltage of all cells excluding the cell in which an abnormality occurs and a pack voltage, and infer a value, which is calculated by subtracting the measured voltage of the all cells from the measured pack voltage, as the voltage of the cell.

6. The module battery system of claim 4, wherein, when a pack voltage of the battery module is not checked, the second problem solving module is configured to block an output to an outside, measure a voltage of all cells and a pack voltage, and recognize the measured voltage of the all cells as the pack voltage when it is determined that there is a pack voltage sensing abnormality.

7. The module battery system of claim 4, wherein, when a temperature of the battery module is not measured, the third problem solving module is configured to block an output to an outside, continuously measure a temperature, determine a case in which a value of the measured temperature expresses a high temperature or low temperature, which is different from a value of the measured nearby temperature, as a sensing error, and check a temperature which is performed by temperature sensing excluding temperature sensing in which abnormality occurs.

8. The module battery system of claim 2, wherein the self-diagnosis module performs the self-diagnosis of the battery module through:
an abnormal state check operation of checking whether the abnormality occurs in each of the battery modules;
an alarm generation operation of outputting and notifying an outside of content of an abnormal state when the abnormality occurs in the battery module;
a stand-by operation of waiting for a predetermined time after generating an alarm; and
an output block operation of blocking an output to the outside when the abnormal state is not solved for the stand-by operation.

9. The module battery system of claim 8, wherein, in the abnormal state check operation, it is checked whether a cell voltage abnormality, a pack voltage abnormality, a temperature abnormality, or a current abnormality occurs in each of the battery modules.

10. The module battery system of claim 2, wherein, when an abnormality occurs in a specific battery module among the plurality of battery modules and the specific battery module is replaced with a new battery module, the self-diagnosis module controls the battery modules to operate normally by measuring differences in voltage and capacity between the battery modules and controlling an output for each battery module even when the battery module is replaced.

11. The module battery system of claim 1, further comprising an external server which is connected to the BMS module through wired or wireless communication to control the BMS module and inputs a command to operate the battery modules.

12. The module battery system of claim 11, wherein the external server includes a database which stores information needed to control the BMS module and pieces of information about states of the battery modules.
